(19) United States
(12) Patent Application Publication
(10) Pub. No.: US 2006/0146163 A1
(43) Pub. Date: Jul. 6, 2006

(54) Color linear image sensor

(75) Inventor: Akira Uemura, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/322,365

(22) Filed: Jan. 3, 2006

(30) Foreign Application Priority Data
Jan. 5, 2005 (JP) 2005-000996

(51) Int. Cl. H04N 5/335

(52) U.S. Cl. 348/311

(57) ABSTRACT

Use of a color linear image sensor including a plurality of pixel lines and CCD lines arranged substantially in parallel and a dummy pattern formed at a chip end side of a pixel line of the plurality of pixel lines that is adjacent to a chip end portion allows the thickness of an on-chip filter to be uniform above pixel lines corresponding to the same color, thereby minimizing nonuniformity in color and sensitivity.

### BACKGROUND OF THE INVENTION

1. Field of the Invention

The present invention relates to a color linear image sensor and, particularly, to a solid-state image sensing device that minimizes thickness irregularity in an on-chip filter.

2. Description of Related Art

Recent color linear image sensors have high resolution. Due to production restrictions, few sensors have a structure that represents one color with a single pixel line. Instead, the color linear image sensors generally have a staggered structure that arranges a plurality of pixel lines in such a way that they are shifted from each other at a pixel pitch of ½, ⅓, ¼ and so on. Recently developed is a color linear image sensor that has this structure and further uses a technique that two pixel lines share one CCD line for chip size reduction, CCD line capacity saving and so on (e.g. Japanese Unexamined Patent Application Publication No. 2001-196571).

FIG. 6 is a block diagram of a color linear image sensor 900 where two pixel lines shares one CCD line. FIG. 7 is a cross-sectional view along line VII-VII in FIG. 6.

This structure transfers charges that occur in two pixel lines through the same CCD line. Since the number of CCD lines is half compared with a color linear image sensor where CCD lines and pixel lines are in one to one correspondence, this structure is effective for reduction in line interval and chip size.

The color linear image sensor 900 includes blue pixel lines 911 and 912, green pixel lines 913 and 914, and red pixel lines 915 and 916. A CCD line 931 is placed between the blue pixel lines 911 and 912. A CCD line 932 is placed between the green pixel lines 913 and 914. A CCD line 933 is placed between the red pixel lines 915 and 916.

Readout gate lines 921 to 926 are respectively placed between the CCD lines 931 to 933 and the pixel lines 911 to 916. The CCD lines 931 to 933 sequentially transfer the charges photoelectrically converted in the pixel lines, which are composed of two lines for each of blue, green and red. The CCD lines 931 to 933 are connected respectively to output circuits 941 to 943.

In the color liner image sensor 900, the pixel lines close to a chip center part have CCD lines formed in both sides thereof, which is the upper side and lower side of the pixel lines in FIG. 7. On the other hand, the pixel lines 911 and 916 closest to the chip end portion have a CCD line formed in one side (the lower side for the pixel line 911 and the upper side for the pixel line 916) but has no CCD line in the other side.

Thus, in the chip end portions located outside the pixel lines 911 and 916, a first polysilicon gate electrode 963, a second polysilicon gate electrode 965, a readout gate electrode 966, and light shielding films 967 and 968 are not formed. Therefore, in the vicinity of the chip end portions, the thickness from the surface of a semiconductor substrate 951 to the surface of a passivation film 956 differs between a region having a CCD n-well 961 and a region not having it (see T1 and T2 in FIG. 7).

If anon-chip filter smoothing film 957 and on-chip filters 958 and 959 are deposited in this state, the on-chip filter 958 drifts from the side where the thickness from the surface of the semiconductor substrate 951 to the surface of the passivation film 956 is larger into the side where the thickness is smaller.

The drift of the on-chip filter 958 causes a difference in sensitivity between pixel lines if a filter thickness differs between the pixel lines of the same color. FIG. 8 shows an example of this case. In the case of the structure that two pixel lines shares one CCD line, a process of reading data from a pixel line to transferring charge through a CCD line is performed in succession for each pixel line, and thus signal output is made in two divided times. The drive timing is as shown in FIG. 8.

First, voltage supply to a readout gate 1 is turned ON to read out charges from one pixel line. After readout to a CCD line and transfer are completed, voltage supply to a readout gate 2 of the other pixel line is turned ON to read out charges to the CCD line. The two pixel lines output a signal alternately. The output signal has such a waveform as shown in FIG. 8, and a sensitivity difference between pixel lines appears between pixel lines of the same color.

The present invention has thus recognized that a conventional linear image sensor in which two pixel lines share one CCD line has a problem that drift of an on-chip filter occurs to cause a difference in thickness of an on-chip filter that is formed above pixel lines corresponding to the same color as indicated by T3 and T4 in FIG. 7. The difference in thickness of the on-chip filter above the pixel lines corresponding to the same color leads to nonuniformity in color and sensitivity.

### SUMMARY OF THE INVENTION

According to an aspect of the present invention, there is provided a color linear image sensor which includes a plurality of pixel lines and CCD lines arranged substantially in parallel and a dummy pattern formed at a chip end side of a pixel line of the plurality of pixel lines that is adjacent to a chip end portion.

Forming a dummy pattern at the chip end side of the pixel line located adjacent to the chip end portion allows the thickness from the surface of a semiconductor substrate to the bottom of an on-chip filter smoothing film to be uniform. The thickness of the on-chip filter is thereby uniform in pixel lines corresponding to the same color, thus preventing sensitivity nonuniformity between pixel lines.

According to another aspect of the present invention, there is provided a method of manufacturing a color linear image sensor, which includes forming a photodiode well and a CCD well above a semiconductor substrate, forming an electrode above the CCD well, forming an interlayer insulating film, a light shielding film and a passivation film all over the semiconductor substrate including the electrode, the light shielding film formed so that an opening exists above the photodiode well, and forming an on-chip filter smoothing film and an on-chip filter all over the passivation film wherein when forming the electrode, a dummy electrode having the same structure as the electrode is formed at a chip end side of a pixel line adjacent to a chip end portion, and when forming the light shielding film, a dummy light shielding film having the same structure as the light shielding film is formed at the same time. Forming the dummy electrode at the same time as forming the electrode above the CCD well and also forming the dummy light shielding film at the same time as forming the light shielding film above the interlayer insulating film allows the thickness from the surface of the semiconductor substrate to the bottom of the on-chip filter smoothing film to be uniform.

According to another aspect of the present invention, there is provided a method of manufacturing a color linear image sensor, which includes forming a photodiode well and a CCD well above a semiconductor substrate, forming an electrode above the CCD well, forming an interlayer insulating film, a light shielding film and a passivation film all over the semiconductor substrate including the electrode, the light shielding film formed so that an opening exists above the photodiode well, and forming an on-chip filter smoothing film and an on-chip filter all over the passivation film, wherein a layer compensating a difference in thickness from a surface of the semiconductor substrate to a bottom of the on-chip filter smoothing film is formed at a chip end side of a pixel line adjacent to a chip end portion. Forming the layer that compensates a difference in the thickness from the surface of the semiconductor substrate to the bottom of the on-chip filter smoothing film allows the thickness from the surface of the semiconductor substrate to the bottom of the on-chip filter smoothing film to be uniform.

A color image sensor and its manufacturing method according to the preset invention allow the thickness of an on-chip filter in pixel lines corresponding to the same color to be uniform with a simple process, thereby minimizing sensitivity nonuniformity.

### BRIEF DESCRIPTION OF THE DRAWINGS

The above and other objects, advantages and features of the present invention will be more apparent from the following description taken in conjunction with the accompanying drawings, in which:

FIG. 1 is a structural view of a first embodiment of the present invention;

FIG. 2 is a cross-sectional view of a first embodiment of the present invention;

FIG. 3 is a structural view of a second embodiment of the present invention;

FIG. 4 is a cross-sectional view of a third embodiment of the present invention;

FIG. 5 is a cross-sectional view of a fourth embodiment of the present invention;

FIG. 6 is a structural view of a conventional color linear image sensor;

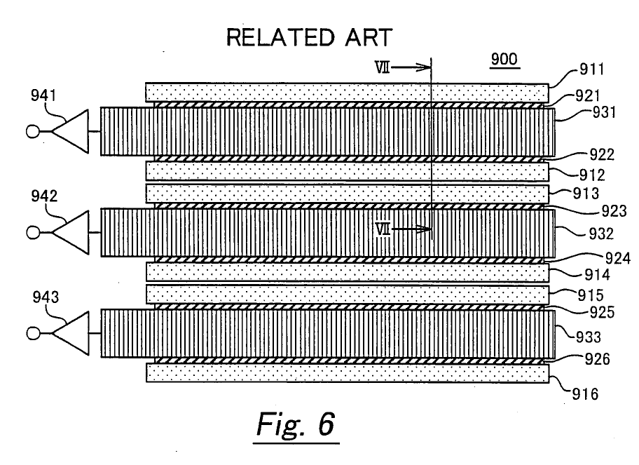

FIG. 7 is a cross-sectional view of a conventional color linear image sensor; and

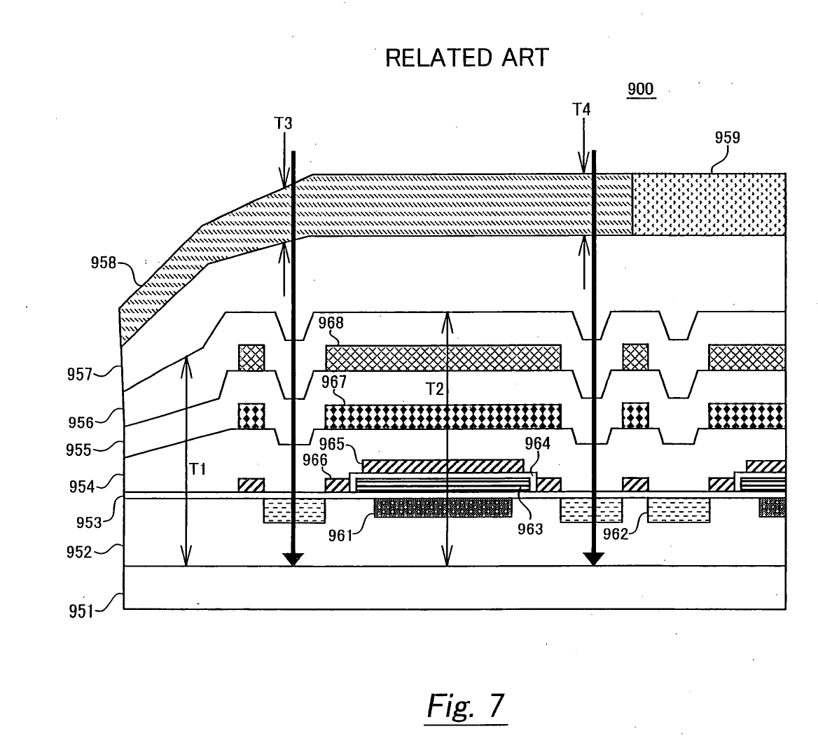

FIG. 8 is a view to describe the operation of a structure where two pixel lines shares one CCD line.

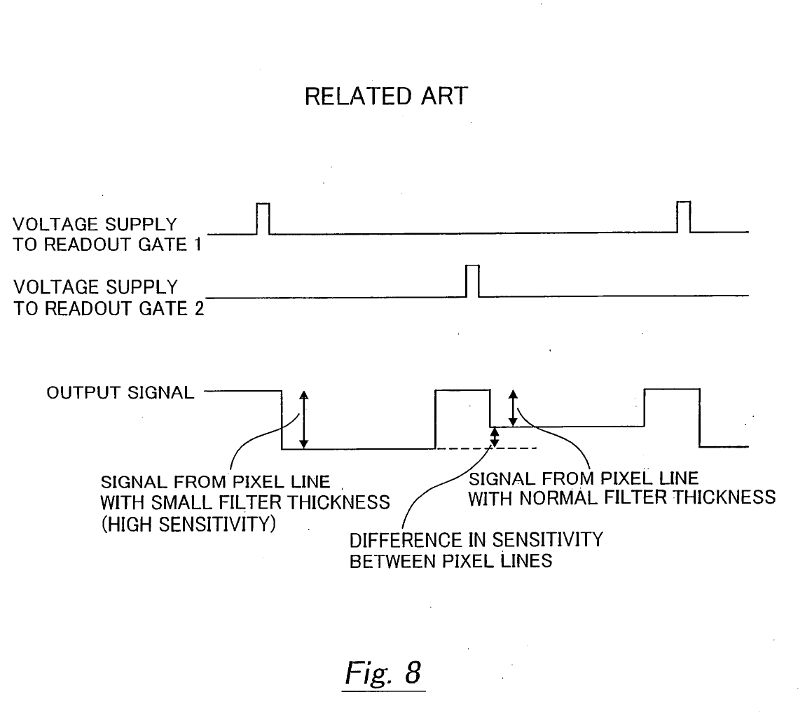

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

First Embodiment

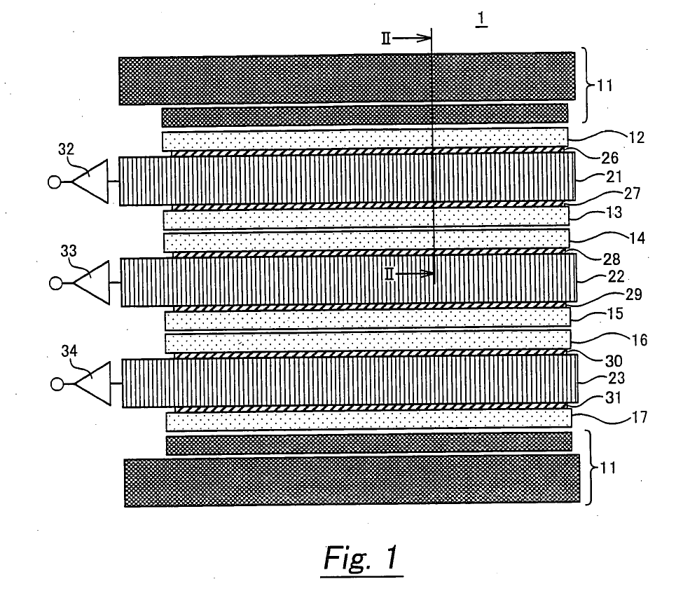

FIG. 1 is a top plan view of a color linear image sensor according to a first embodiment of the preset invention. The structure of the color linear image sensor of this embodiment is described hereinafter with reference to FIG. 1.

A color liner image sensor 1 of the first embodiment includes pixel lines 12 to 17, CCD lines 21 to 23, readout gate lines 26 to 31, and dummy pattern 11. The pixel lines 12 to 17, CCD lines 21 to 23, readout gate lines 26 to 31, and dummy pattern 11 are arranged substantially in parallel with each other along a predetermined direction, which is a horizontal direction in FIG. 1. The two dummy patterns 11 are placed in the outermost portion of the color linear image sensor so that the pixel lines 12 to 17 and the CCD lines 21 to 23 are placed between them.

In the first embodiment, one CCD line is provided for each color component. Since the color components are three colors of blue, green and red in this embodiment, three CCD lines 21 to 23 are used.

Further, two pixel lines are provided for each of the color components. This embodiment arranges the CCD lines corresponding to each color component between two pixel lines corresponding to each color component. The readout gate lines 26 to 31 are respectively placed between the pixel lines 12 to 17 and the CCD lines 21 to 23.

In this structure, the pixel lines 12 and 13 that correspond to blue share the CCD line 21, for example, thus reducing an area for the CCD lines. Two pixel lines sandwich one CCD line and each readout gate line is placed between each pixel line and CCD line, thereby forming a set of structure for transferring a signal charge corresponding to one color component. This is referred to herein as the image sensor line. Each image sensor line is connected to output circuits 32 to 34.

In the first embodiment, the pixel lines 12 and 13 are formed to sandwich the CCD line 21 corresponding to blue and the readout gate lines 26 and 27 are placed therebetween. The pixel lines 14 and 15 are formed to sandwich the CCD line 22 corresponding to green and the readout gate lines 28 and 29 are placed therebetween. Further, the pixel lines 16 and 17 are formed to sandwich the CCD line 23 corresponding to red and the readout gate lines 30 and 31 are placed therebetween.

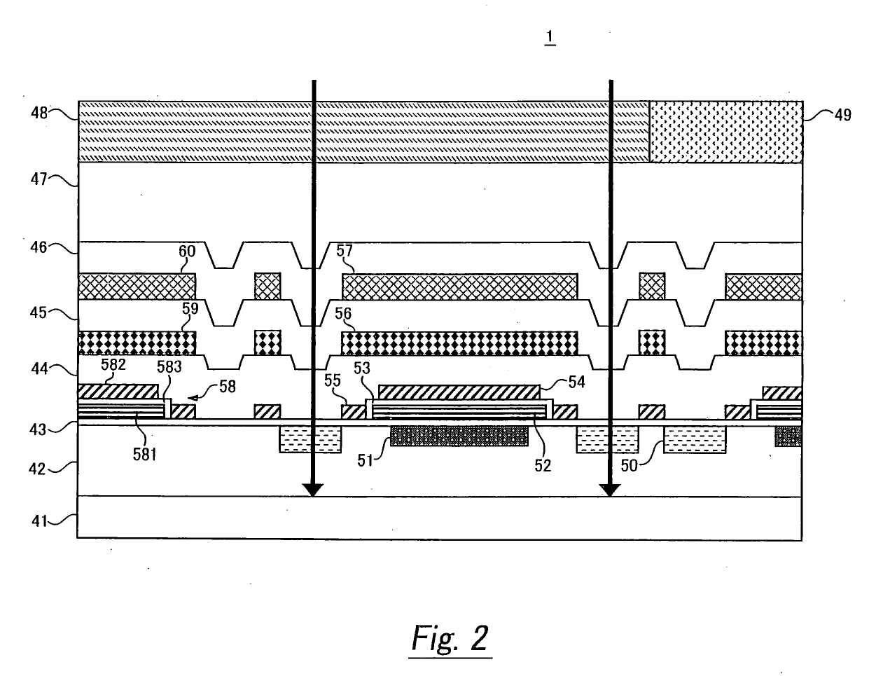

In this embodiment, the three image sensor lines formed as above are placed between the dummy patterns 11. The dummy patterns 11 are detailed later with respect to FIG. 2.

The pixel lines 12 to 17 have a plurality of pixels. The pixels implement photoelectric conversion that converts input light into a signal charge and accumulation of the signal charges that have been generated by the photoelectric conversion. The readout of signal charges from the pixel lines 12 to 17 into the CCD lines 21 to 23 is performed by applying a predetermined voltage to the readout gate lines 26 to 31.

The signal charges that have been readout to the CCD lines 21 to 23 are transferred to the output circuits 32 to 34, respectively, by applying a predetermined signal to CCD gates. The output circuits 32 to 34 convert the signal charges transferred from the CCD lines 21 to 23 into a voltage signal and amplify the signal.

FIG. 2 shows a cross-sectional view along line II-II in FIG. 1. The cross-sectional structure of the color linear image sensor 1 of this embodiment is described hereinafter with reference to FIG. 2.

In the color linear image sensor 1, a p-well layer 42 is formed on an n-type semiconductor substrate 41 by ion implantation, for example. In the p-well layer 42, photodiode n-well 50 and CCD n-well 51 are formed in the positions corresponding to the pixel lines 12 to 17 and the CCD lines 21 to 23 in FIG. 1, respectively, by ion implantation, for example.

The photodiode n-well 50 implements photoelectric conversion and accumulation of charges generated by the photoelectric conversion. The region of the photodiode n-well 50 serves as a pixel. The pixels are arranged in line to form the pixel lines 12 to 17. The charges generated in the photodiode n-well 50 are transferred along the depth direction in FIG. 2 by changing a voltage supplied to the gate of the CCD n-well 51 appropriately.

A gate oxide film 43 is formed all over the semiconductor substrate. On the gate oxide film 43, at a given position above the region corresponding to the CCD line 21 to 23 in FIG. 1, a first polysilicon gate electrode 52 that is made of a first polysilicon layer is formed by CVD and etching, for example.

Besides the position above the CCD n-well 51 corresponding to the CCD lines 21 to 23, the electrode made of the first polysilicon layer is also formed as a first dummy gate electrode 581 on the gate oxide film 43 at a position corresponding to the dummy pattern 11 in FIG. 1, which is outside of the pixel lines 12 to 17, in this embodiment.

Above the first polysilicon gate electrode 52, a second polysilicon gate electrode 54 that is made of a second polysilicon layer is formed by CVD and etching, for example, with an oxide film 53 interposed therebetween.

The second polysilicon layer is formed also in the regions between the pixel lines 12 to 17 and the CCD lines 21 to 23 and patterned as a readout gate electrode 55 to serve as the readout gate lines 26 to 31. Like the first polysilicon gate electrode, the second polysilicon layer is formed also as a second dummy gate electrode 582 above the first dummy gate electrode 581 that corresponds to the dummy pattern 11 in FIG. 1 with an insulating film 583 interposed therebetween.

The first polysilicon gate electrode 52 and the second polysilicon gate electrode 54 supply voltages to the CCD n-well 51 for charge transfer. The readout gate electrode 55 is placed for charge readout from the photodiode n-well 50 to the CCD n-well 51.

Further, interlayer insulating films 44 and 45 and light shielding films 56 and 57 are formed by CVD and etching, for example, all over the structure where the first and second polysilicon gate electrodes are formed in the positions corresponding to the CCD lines 21 to 23 and the dummy patterns 11.

The light shielding films 56 and 57 have openings at the positions corresponding to the pixel lines 12 to 17 so as to pass through the incident light as indicated by arrows in FIG. 2. The light shielding films 56 and 57 are also placed as dummy shielding films 59 and 60 at the position corresponding to the dummy pattern in FIG. 1.

Thus, the image sensor 1 of the first embodiment has the first polysilicon gate 52, the second polysilicon gate electrode 54 and the light shielding films 56 and 57 at the positions corresponding to the CCD lines 21 to 23 in FIG. 1 and also has the dummy gate electrode 58, the dummy light shielding films 59 and 60 and so on at the positions outer than the pixel lines 12 and 17 at the chip end portion. The dummy gate electrode 58 refers to the part that includes the first dummy gate electrode 581, the second dummy gate electrode 582 and the insulating film 583.

In the first embodiment, a passivation film 46, an on-chip filter smoothing film 47 and on-chip filters 48 and 49 are deposited by CVD, for example, all over the structure that includes the dummy gate electrode 58 and the dummy light shielding films 59 and 60.

The dummy pattern 11 does not require wiring since there is no need to accumulate or transfer charges. Thus, in no case the dummy pattern 11 causes an increase in the terminal capacity of the CCD lines 21 to 23 to affect the transfer. Further, since the chip width of the color linear image sensor is determined by the layout of the output circuits 32 to 34, there is a sufficient space for the dummy pattern 11. Thus, it hardly causes an increase in chip size.

As shown in FIGS. 1 and 2, the color image sensor 1 of the first embodiment has the dummy gate electrode 58 and the dummy light shielding films 59 and 60 as the dummy pattern 11 in the position outside of the pixel line at the chip end portion so that they have the same height as the CCD lines 21 to 23. It is therefore possible to reduce a difference in thickness from the surface of the semiconductor substrate 41 to the bottom of the on-chip filter smoothing film 47 in the vicinity of the pixel lines 12 and 17 at the outermost portion.

This prevents the drift of the on-chip filter smoothing film 47 and the on-chip filters 48 and 49 toward the chip outermost portion, thereby minimizing a difference between a filter thickness above the pixel line 12 and a filter thickness above the pixel line 13, both corresponding to blue, for example.

As described in the foregoing, forming the dummy gate electrode and the dummy light shielding films as the dummy pattern in the outside of the pixel line at the outermost portion allows the thickness of the on-chip filter in the pixel lines corresponding to the same color to be substantially uniform, thus minimizing sensitivity nonuniformity between pixel lines of the same color.

Second Embodiment

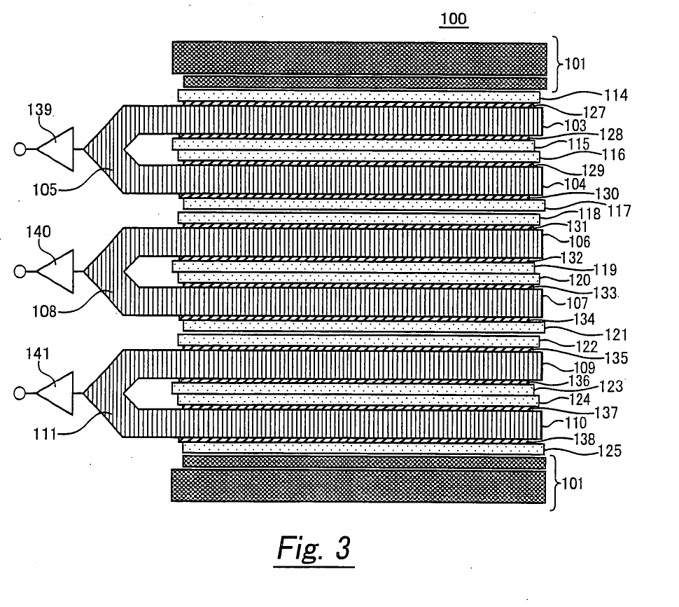

The structure of a color linear image sensor 100 according to a second embodiment of the present invention is described hereinafter with reference to FIG. 3. The color linear image sensor 100 of the second embodiment is for high resolution use. The operation principle and formation process are the same as those of the first embodiment and thus not described herein.

The color linear image sensor 100 of the second embodiment includes pixel lines 114 to 125, CCD lines 103 to 110, readout gate lines 127 to 138 and dummy patterns 101, which are arranged substantially in parallel along a predetermined direction, which is a horizontal direction in FIG. 3. The dummy patterns 101 are placed in the outermost portions of the color linear image sensor 100 so that the pixel lines 114 to 125 and the CCD lines 103 to 110 are placed between them.

The pixel lines 114 to 125 are composed of four lines per color, with a staggered structure where the lines are shifted from each other at ¼ pixel pitch. The readout gate lines 127 to 138 are placed between each of the pixel lines 114 to 125 and the CCD lines 103 to 110. The CCD lines 103 and 104, which correspond to blue, are merged into one line at the end portion 105. The CCD lines 106 and 107, which correspond to green, are merged into one line at the end portion 108. The CCD lines 109 and 110, which correspond to red, are merged into one line at an end portion 111. The end portions 105, 108 and 111 of the CCD lines are connected to the output circuits 139 to 141.

In the second embodiment of the invention, the pixel lines 114 to 125 and the CCD lines 103 to 110 formed as above are placed between the dummy patterns 101. As is the case with the first embodiment, the dummy patterns 101 includes a dummy electrode and a dummy light shielding film that are formed in the outside of the pixel lines 114 and 125 at the outermost portions. This allows the thickness from the surface of the semiconductor to the bottom of the on-chip filter smoothing film to be substantially uniform. The thickness of an on-chip filter is thus substantially uniform, thereby minimizing sensitivity nonuniformity between pixel lines.

In the second embodiment, an area per unit pixel is small due to high resolution and therefore a slight difference in shape significantly affects sensitivity. Application of this invention makes it possible to easily equalize the flatness in the vicinity of the pixel line at the outermost portion with the flatness in the other portion, thus achieving sensitivity uniformity in high resolution devices. This structure is also applicable to the structure that includes three, four, five or more CCD lines for each color, each having pixel lines in both sides.

Third Embodiment

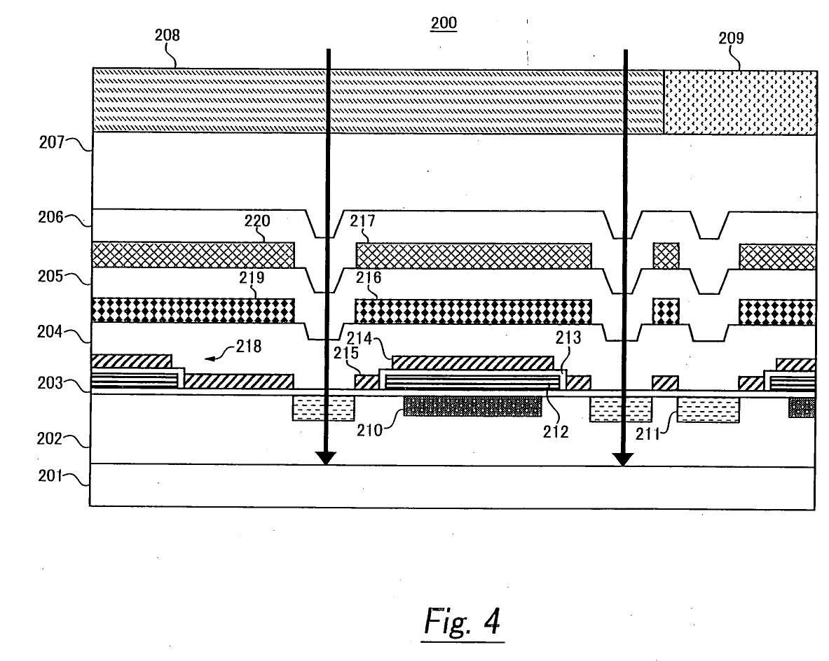

FIG. 4 shows a cross-sectional view of a color linear image sensor 200 according to a third embodiment of the present invention. The third embodiment places a dummy electrode 218 and dummy light shielding films 219 and 220 in the positions corresponding to outside of a pixel line in the outermost portion just like in the first embodiment. The operation principle is the same as in the first embodiment and thus not described herein.

The third embodiment is different from the first embodiment in that the dummy electrode 218 and the dummy light shielding films 219 and 220 lie perpendicularly to pixel lines, CCD lines, and there is no opening outside the pixel line in the outermost portion.

Since no opening exists outside the pixel line in the outermost portion, it is possible to reduce excess charges that occur in an opening made at a position corresponding to the dummy pattern. This eliminates the possibility that excess charges flow into the pixel line in the outermost portion to generate a false signal.

Fourth Embodiment

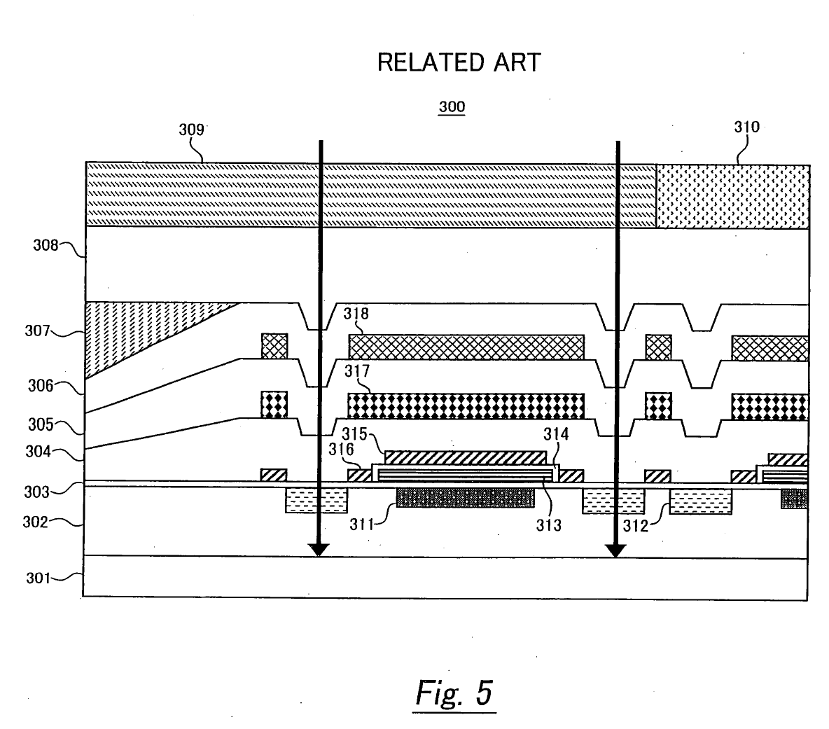

FIG. 5 shows a cross-sectional view according to a fourth embodiment of the present invention. The fourth embodiment does not place a dummy electrode and a dummy light shielding film in an outside of a pixel line at an outermost portion, which is different from the first to third embodiments.

A p-well layer 302 is formed on a semiconductor substrate 301 by ion implantation, for example. In the p-well layer 302, a CCD n-well 311 and a photodiode n-well 312 are formed by ion implantation, for example. A gate oxide film 303 is formed all over the semiconductor substrate by CVD and annealing, for example.

On the gate oxide film 303, a first polysilicon electrode 313 that is made of a first polysilicon layer is formed by CVD and etching, for example. Above the first polysilicon electrode 313, a second polysilicon gate electrode 315 that is made of a second polysilicon layer is formed by CVD and etching, for example, with an insulating film 314 interposed therebetween. A readout gate electrode 316, which is also made of the second polysilicon layer, is placed between the insulating film 314 and the photodiode n-well 312.

Further, interlayer insulating films 304 and 305 and light shielding films 317 and 318 are formed by CVD and etching, for example, all over the above structure. The light shielding films 317 and 318 are formed so that openings exist above the photodiode n-well 312.

All over the interlayer insulating film 305, a passivation film 306 is formed by CVD, for example. This structure is the same as the conventional technique, and a difference occurs in the thickness from the surface of the semiconductor to the surface of the passivation film 306 in the region outside the pixel line at the outermost portion.

The fourth embodiment creates a step adjusting layer 307 to cover the difference from the surface of the semiconductor to the surface of the passivation film 306. The step adjusting layer 307 is formed to make the thickness from the surface of the semiconductor substrate 301 to the surface of the passivation film 306 uniform in the region outside the pixel line at the outermost portion. This layer may be formed of semiconductor, metal, insulator, or the like.

The step adjusting layer 307 is formed before forming the on-chip filter smoothing film 308. It is deposited thickly by CVD, for example, by masking the region different from the region outside the pixel line at the outermost portion. Then, the part that is thicker than the other part is cut off, thereby making the thickness from the surface of the semiconductor substrate 301 to the bottom of the on-chip filter smoothing film 306 uniform.

After that, the on-chip filter smoothing film 308 and on-chip filters 309 and 310 are formed by CVD, for example, all over the structure that is formed as above.

The first to third embodiments equalize the thickness from the surface of the semiconductor substrate 301 to the surface of the passivation film 306 by forming a dummy electrode and a dummy light shielding film. The fourth embodiment, on the other hand, equalize the thickness from the surface of the semiconductor substrate 301 to the surface of the passivation film 306 by using the step adjusting layer 307. It is thereby possible to suppress the drift of the on-chip filters 309 and 310, thereby minimizing sensitivity nonuniformity in pixel lines of the same color.

It is apparent that the present invention is not limited to the above embodiment that may be modified and changed without departing from the scope and spirit of the invention.

What is claimed is:

1. A color linear image sensor comprising:
a plurality of pixel lines;
a plurality of CCD lines arranged substantially parallel with the plurality of pixel lines; and
a dummy pattern formed at a chip end side of a pixel line of the plurality of pixel lines that is adjacent to a chip end portion.

2. The color linear image sensor according to claim 1, wherein the dummy pattern comprises a dummy electrode and a dummy light shielding film.

3. The color linear image sensor according to claim 2, wherein in the dummy pattern, the dummy electrode and the dummy light shielding film lie at the chip end side of the pixel line that is adjacent to the chip end portion.

4. The color linear image sensor according to claim 1, further comprising:
a step adjusting layer compensating a difference in thickness from a surface of a semiconductor to a bottom of an on-chip filter smoothing film, formed at the chip end side of the pixel line that is adjacent to the chip end portion.

5. A method of manufacturing a color linear image sensor, comprising:
forming a photodiode well and a CCD well above a semiconductor substrate;
forming an electrode above the CCD well;
forming an interlayer insulating film, a light shielding film and a passivation film all over the semiconductor substrate including the electrode, the light shielding film formed so that an opening exists above the photodiode well; and
forming an on-chip filter smoothing film and an on-chip filter all over the passivation film,
wherein the forming the electrode includes forming a dummy electrode having the same structure as the electrode at a chip end side of a pixel line adjacent to a chip end portion, and the forming the light shielding film includes forming a dummy light shielding film having the same structure as the light shielding film.

6. A method of manufacturing a color linear image sensor, comprising:
forming a photodiode well and a CCD well above a semiconductor substrate;
forming an electrode above the CCD well;
forming an interlayer insulating film, a light shielding film and a passivation film all over the semiconductor substrate including the electrode, the light shielding film formed so that an opening exists above the photodiode well; and
forming an on-chip filter smoothing film and an on-chip filter all over the passivation film,
wherein a layer compensating a difference in thickness from a surface of the semiconductor substrate to a bottom of the on-chip filter smoothing film is formed at a chip end side of a pixel line adjacent to a chip end portion.
